(19) United States
(12) Patent Application Publication
(10) Pub. No.: US 2015/0214097 A1
(43) Pub. Date: Jul. 30, 2015

(54) METHOD FOR MANUFACTURING SHALLOW TRENCH ISOLATION

(71) Applicants: Haizhou Yin, Poughkeepsie, NY (US); Keke Zhang, Shandong (CN)

(72) Inventors: Haizhou Yin, Poughkeepsie, NY (US); Keke Zhang, Shandong (CN)

(21) Appl. No.: 14/413,966

(22) PCT Filed: Aug. 3, 2012
(86) PCT No.: PCT/CN2012/079693

§ 371 Date: Jan. 9, 2015

(30) Foreign Application Priority Data
Jul. 13, 2012 (CN) 201210244781.X

(51) Int. Cl. H01L 21/762; H01L 21/3065; H01L 29/06; H01L 21/3105; H01L 21/02; H01L 21/306; H01L 21/308

(52) U.S. Cl. CPC H01L 21/76229; H01L 21/30604; H01L 21/3065; H01L 21/3081; H01L 21/31053; H01L 21/0214; H01L 21/02164; H01L 21/0217; H01L 21/02192; H01L 21/02194; H01L 21/02189; H01L 29/0649

(57) ABSTRACT

The present invention provides a method for manufacturing a shallow trench isolation, comprising: forming a hard mask layer on the substrate; phottoetching/etching the hard mask layer and the substrate to form a plurality of first trenches along a first direction and a plurality of second trenches along a second direction perpendicular to the first direction, wherein the volume of the second trench is greater than that of the first trench; depositing an insulating material in the first and second trenches; planarizing the insulating material and the hard mask layer until the substrate is exposed so as to form a shallow trench isolation. According to a method of the present invention, the shallow trench isolation is allowed by etch-filling to be deep and wide in the channel width direction and shallow and narrow in the channel length direction, and stress is applied to NMOS and PMOS simultaneously to increase the carrier mobility of the channel region, thereby improving the overall driving capability of the device.

This application claims the benefits of prior Chinese Patent Application No. 201210244781.X filed on Jul. 13, 2012, titled “METHOD FOR MANUFACTURING SHALLOW TRENCH ISOLATION (STI)”, which is incorporated herein by reference in its entirety.

### TECHNICAL FIELD

The present invention relates to the field of manufacturing semiconductor integrated circuits. In particular, the present invention relates to a method for manufacturing a shallow trench isolation having different stress in different directions.

### BACKGROUND ART

Although the overall properties of devices improve continuously as the device sizes decrease, the driving capability of the devices seems increasingly inadequate since, e.g., the carrier mobility of the MOSFET channel region is limited by the material and technology and does not have a great improvement accordingly. In order to improve the carrier mobility and enhance the driving capability of the devices, an alternative approach in the prior art is to apply stress to MOSFET. For example, as for NMOS of (100)/<110>, tensile stress is applied in the direction of the channel length (along the source region-channel region-drain region, which may be hereinafter referred to as a second direction), and tensile stress is applied in the direction of the channel width (along the gate extension, perpendicular to the length direction and the second direction, which may be hereinafter referred to as a first direction); as for PMOS, compressive stress is applied in the direction of the channel length, and tensile stress is applied in the direction of the channel width. Such biaxial stress structure/method can increase the carrier mobility of electrons in the NMOS channel region and holes in the PMOS channel region, respectively, thereby correspondingly improving the driving capability.

The existing structure/method for applying stress to a channel region includes substrate-induced biaxial strain and process-induced uniaxial strain. Substrate-induced biaxial strain means manufacturing MOS devices on a lattice mismatched substrate (e.g., SiGe), where the channel is subjected to biaxial stress in the direction parallel to the substrate due to its mismatch with substrate lattice. Process-induced uniaxial strain comprises: a Σ-type embedded stressed source/drain regions of SiGe or Si:C, a stressed gate spacer of silicon nitride or diamond-like amorphous carbon (DLC) material, a stressed cap layer of silicon nitride or diamond-like amorphous carbon (DLC) material covering the entire device, shallow trench isolation (STI) having stress, and so on. Theoretical calculations and actual test data prove that process-induced uniaxial strain exhibits better effects when the device feature size shrinks continuously.

At the same time, as the device feature size shrinks continuously below 32 nm, the above structures/methods applying stress have to face many problems such as the insufficient precision of lithography/etching, decrease in the material deposit-filling rate, and the insufficient distance to the channel region. Since NMOS and PMOS generally have the same gate direction and channel region direction, stress STI with an easy quality control is becoming an important choice to enhance carrier mobility.

Although the existing stress STI technique can apply different types of stresses to centrally distributed NMOS and PMOS, it is difficult to use a simple process to apply different types of stresses for the case of mixed distribution. Thus, it is difficult to uniformly improve the mobility of two MOSFET's simultaneously. Furthermore, STI technique in which different types of stresses are formed in at least two steps also increases the complexity of the process, and increases the time and manufacturing cost.

### SUMMARY OF THE INVENTION

In view of the above, an object of the present invention is to apply stress to NMOS and PMOS simultaneously by the existing simple process to increase the carrier mobility of the channel region, thereby improving the overall driving capability of the device.

The above object of the present invention is achieved by providing a method of manufacturing a shallow trench isolation, comprising: forming a hard mask layer on the substrate; phottoetching/etching the hard mask layer and the substrate to form a plurality of first trenches along a first direction and a plurality of second trenches along a second direction perpendicular to the first direction, wherein the volume of the second trench is greater than that of the first trench; depositing an insulating material in the first and second trenches; and planarizing the insulating material and the hard mask layer until the substrate is exposed so as to form the shallow trench isolation.

The hard mask layer comprises at least one material selected from a group consisting of silicon oxide, silicon nitride, and silicon oxynitride.

The step for forming the plurality of first trenches and the plurality of second trenches further comprises: phottoetching/etching the hard mask layer to form a hard mask pattern along the first direction until the substrate is exposed; etching the substrate to form the first trenches; subject the hard mask layer to photolithography/etching to form a hard mask pattern along the second direction until the substrate is exposed; and etching the substrate to form the second trenches.

The step for forming the plurality of first trenches and the plurality of second trenches further comprises: phottoetching/etching the hard mask layer to form a hard mask pattern along the second direction until the substrate is exposed; etching the substrate to form the second trenches; phottoetching/etching the hard mask layer to form a hard mask pattern along the first direction until the substrate is exposed; and etching the substrate to form the first trenches.

The step for forming the plurality of first trenches and the plurality of second trenches further comprises: phottoetching/etching the hard mask layer to form a grid-like hard mask pattern having a plurality of openings along the first direction and the second direction; and etching the substrate to form the first trenches and the second trenches at the same time.

The second trenches are wider than the first trenches.

The second trenches are deeper than the first trenches.

The insulating material comprises silicon oxide, silicon nitride, silicon oxynitride, Bi_{0.95}La_{0.05}NiO₃, BiNiO₃, or ZrW₂O₈.

The shallow trench isolation applies tensile stress to the substrate.

The first direction is the width direction of the device channel region, and the second direction is the length direction of the device channel region.

The present invention also provides a semiconductor device including a substrate and a shallow trench isolation formed of an insulating material in the substrate, characterized in that: the volume of the shallow trench isolation in the second direction is greater than that of the shallow trench isolation in the first direction.

According to a method of the present invention, the shallow trench isolation is allowed by etch-filling to be deep and wide in the channel width direction and shallow and narrow in the channel length direction, and stress is applied to NMOS and PMOS simultaneously to increase the carrier mobility of the channel region, thereby improving the overall driving capability of the device.

### BRIEF DESCRIPTION OF THE FIGURES

The technical solutions of the present invention are described in detail with reference to the figures, wherein:

FIG. 1 is a flowchart of a method of manufacturing a shallow trench isolation according to the present invention;

FIG. 2 is a sectional view of a method of manufacturing a shallow trench isolation according to the present invention, wherein the hard mask layer is deposited on the substrate;

FIG. 3 is a top view of a method of manufacturing a shallow trench isolation according to the present invention, wherein a plurality of parallel first trenches along the channel width direction are etched;

FIG. 4 is a top view of a method of manufacturing a shallow trench isolation according to the present invention, wherein a plurality of parallel is second trenches along the channel length direction are etched;

FIG. 5 is a sectional view of a method of manufacturing a shallow trench isolation according to the present invention, which shows a plurality of first trenches along the AA′ direction illustrated in FIG. 3 or 4;

FIG. 6 is a sectional view of a method of manufacturing a shallow trench isolation according to the present invention, which shows a plurality of second trenches along the BB′ direction illustrated in FIG. 4;

FIG. 7 is a sectional view of a method of manufacturing a shallow trench isolation according to the present invention, wherein a plurality of first trenches illustrated in FIG. 5 are filled;

FIG. 8 is a sectional view of a method of manufacturing a shallow trench isolation according to the present invention, wherein a plurality of second trenches illustrated in FIG. 6 are filled;

FIG. 9 is a sectional view of a method of manufacturing a shallow trench isolation according to the present invention, wherein the structure illustrated in FIG. 7 is planarized until the substrate is exposed; and

FIG. 10 is a sectional view of a method of manufacturing a shallow trench isolation according to the present invention, wherein the structure illustrated in FIG. 8 is planarized until the substrate is exposed.

### DESCRIPTION OF THE PREFERRED EMBODIMENTS

The characteristics and technical effects of the technical solution of the present invention is described in detail referring to the figures in combination with schematic embodiments. What should be noted is that: similar reference signs denote similar structures, and the terms “first”, “second”, “above”, “below”, “thick”, “thin”, and so on used in the present application can be used for modifying various device structures. These modifications, unless otherwise stated, do not imply the space, order, or hierarchical relationship of the device structure modified.

FIG. 1 is a flowchart of a method of manufacturing a shallow trench isolation according to the present invention, wherein the steps of the method of the invention will be described in detail with reference to the flowchart of FIG. 1 and FIG. 2 to FIG. 10.

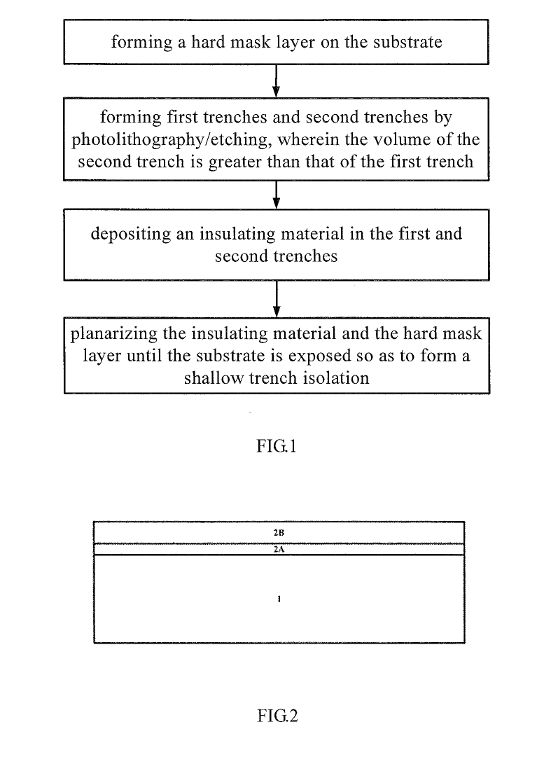

Referring to FIG. 1 and FIG. 2, a hard mask layer 2 is deposited on a substrate 1. A substrate 1 is provided, where its material may be (body) Si (for example, single crystal Si wafer), SOI, GeOI (Ge on insulator), and may also be other compound semiconductors, such as GaAs, SiGe, GeSn, InP, InSb, GaN, and so on. Preferably, body Si or SOI is selected for the substrate 1 so as to be compatible with the CMOS process. A conventional method such as LPCVD, PECVD, HDPCVD, MOCVD, MBE, ALD, evaporation, and thermal oxidation can be used to deposit the hard mask layer 2 on the substrate 1. The material of the hard mask layer 2 includes, for example, silicon oxide, silicon nitride, silicon oxynitride, or any combination thereof. The hard mask layer 2 may be a single layer, or any combination of the above materials (e.g., a laminate). Preferably, in the embodiments of the present invention, the hard mask layer 2 comprises a pad oxide layer 2A and a mask cap layer 2B which are vertically stacked. The pad oxide layer 2A comprises for example silicon oxide or silicon nitride oxide with a thickness of, for example, 1 to 5 nm, which is used for protecting the substrate surface upon etching so as to avoid increasing defects that would affect the device performance. The material of the mask cap layer 2B is, for example, silicon nitride, having a thickness of, for example, 10 to 30 nm.

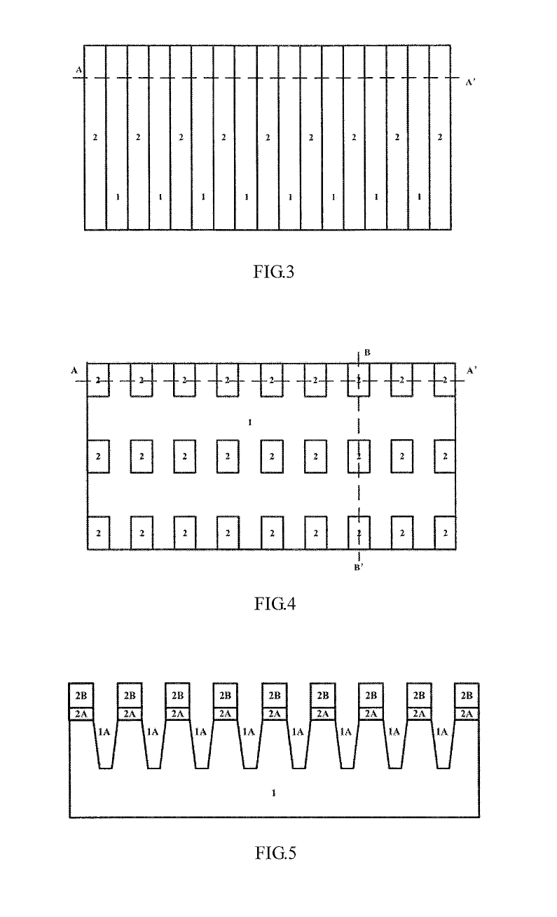

Referring to FIG. 1 and FIG. 3, FIG. 5, the hard mask layer 2 is etched along the first direction (the channel width direction of a device to be formed, for example, MOSFET, i.e., the direction in which the gate to be formed will extend) until the substrate 1 is exposed to form a hard mask pattern; then the substrate 1 is further etched to form a plurality of parallel first trenches 1A. The etching method is selected according to the materials of the hard mask layers 2A/2B and the substrate 1, such that the materials of various layers have a high etching selection ratio, wherein dry etching such as fluorocarbon-based gas plasma etching can be used. The width of a single first trench 1A (along the second direction perpendicular to the first direction), for example 20 to 100 nm, is used for the portions on both sides of the shallow trench isolation to be formed in the length direction of the channel region. The distance between the plurality of first trenches 1A is, for example, 200 to 2000 nm, dividing the active region from the device along the is length direction of the channel region. FIG. 5 is a sectional view of FIG. 3 along AA′, which shows that the first trench 1A has a narrower width, and preferably, has a shallower depth which is for example 50 to 200 nm.

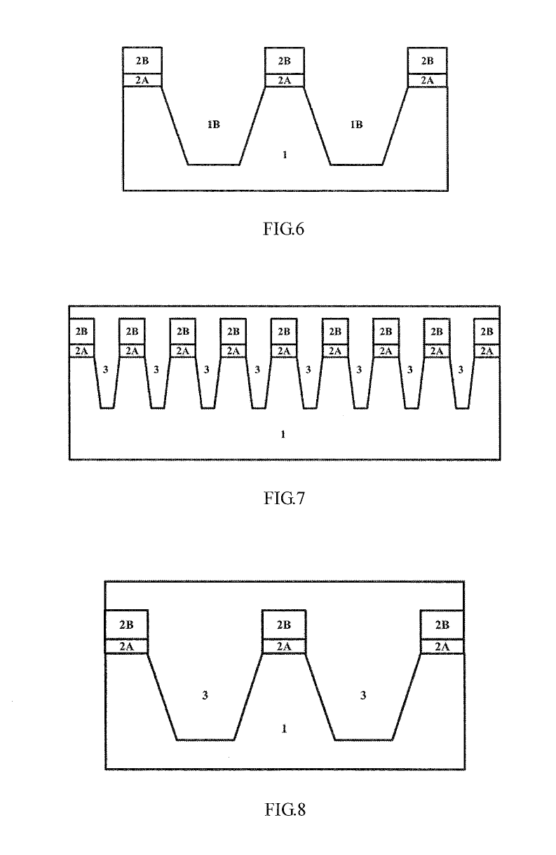

Referring to FIG. 1 and FIG. 4, FIG. 6, the hard mask layer 2 is further etched along the second direction (the length direction of the channel region of an MOSFET device to be formed, i.e., the direction in which the source region-channel region-drain region extends and distributes, preferably perpendicular to the aforementioned first direction) to form a hard mask pattern; then the substrate 1 is further etched to form a plurality of parallel second trenches 1B. Similarly, the above drying etching can be used to form a second trench 1B. The volume of the second trench 1B is greater than that of the first trench 1A such that the volume at both ends in the width direction of the channel region of STI to be formed is greater than the volume at both ends in the length direction of the channel region, and thus the stress applied in the width direction of the channel region of the device is greater than the stress in the length direction of the channel region of the device. For example, a single second trench 1B itself has a width (along the first direction perpendicular to the second direction) of for example 50 to 300 nm which is greater than that of a single first trench 1A. The distance between the plurality of second trenches 1B is, for example, 200 to 1000 nm, dividing the active region from the device along the length direction of the channel region. FIG. 6 is a sectional view of FIG. 4 along BB′, and compared with FIG. 5, the width of the second trench 1B is greater than that of the first trench 1A. And preferably, the depth of the second trench 1B is for example 10 to 300 nm, which is also greater than that of the first trench 1A. The embodiments show that a first trench and a second trench may be etched successively; alternatively, a first trench may be etched after the second trench, the etching step and parameters being similar to that described above. The embodiments show that the volume of the second trench 1B greater than that of the first trench 1A is achieved by a greater width and a greater depth, but it can also be achieved by the same width and a greater depth, or the same depth and a greater width. In addition, FIGS. 3 to 6 show the order of first forming a hard mask pattern and a first trench and then forming a hard mask pattern and a second trench in the embodiments, but other implementation processes can also be used in the modified examples. For example, a grid-like lithography mask plate is used for disposable photolithography/etching of the hard mask to form a grid-like hard mask pattern as shown in FIG. 4 (i.e., having a plurality of openings in the first direction and in the second direction), followed by disposable dry etching to form a first trench 1A and a second trench 1B in FIG. 5 and FIG. 6, wherein the two trenches may have the same depth but different width; or the etching sequence as shown in FIGS. 3 to 6 is used, i.e., the first trench and the second trench are etched successively, wherein the two trenches have the same width and the depth of the second trench 1B is greater than that of the first trench 1A. Alternatively, the step of forming a plurality of first trenches and a plurality of second trenches further comprises: phottoetching/etching the hard mask layer to form a hard mask pattern along the second direction until the substrate is exposed; etching the substrate to form the second trench; phottoetching/etching the hard mask layer to form a hard mask pattern along the first direction until the substrate is exposed; and etching the substrate to form the first trench.

Afterwards, with reference to FIG. 1, FIG. 7 and FIG. 8, an insulating material 3 is deposited simultaneously in the first trench 1A and the second trench 1B as STI and provides stress. The deposition method is, for example, a conventional method such as PECVD and HDPCVD. The stress is adjusted by controlling the deposition process parameters, for example, the absolute value of stress is 600 MPa to 2 GPa. Preferably, the insulating material 3 applies tensile stress to the substrate 1. The insulating material 3 may be a conventional silicon oxide, silicon nitride, silicon oxynitride, or a negative thermal expansion medium material, e.g., a perovskite-type oxide such as Bi_{0.95}La_{0.05}NiO₃, BiNiO₃, and ZrW₂O₈, which has an absolute value of linear volumetric expansion coefficient of greater than 10⁻⁴ at a temperature of 100K. The insulating material 3 having tensile stress applies tensile stress in the second trench 1B which is greater than the tensile stress applied in the first trench 1A. Thus, for NMOS, the high tensile stress applied in the width direction of the channel region of the device is significantly increased, thereby increasing the carrier mobility of electrons in the channel region. For PMOS, no compressive stress is applied in the length direction of the channel region of the device, but since great tensile stress is also applied in the width direction of the channel region, the degradation of PMOS performance is partly offset, i.e., the significant improvement of NMOS driving capability makes up the insufficient improvement of PMOS driving capability, thereby improving the driving capability of the entire IC.

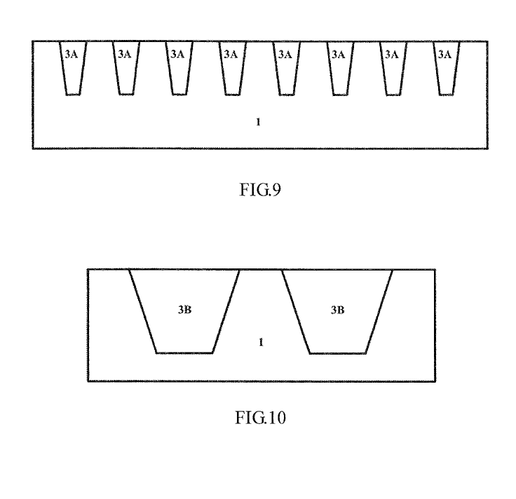

Finally, with reference to FIG. 1, FIG. 9 and FIG. 10, the insulating material 3 and the hard mask layer 2 are planarized using technologies such as back etching or CMP until the substrate 1 is exposed, forming a final shallow trench isolation 3A/3B, wherein the volume of portion 3A of STI distributed in the first direction is less than that of the portion 3B distributed in the second direction. Therefore, the shallow trench isolation formed in accordance with the manufacturing method of the present invention has a volume in the width direction of the channel region of the device greater than that in the length direction of the channel region of the device, so as to apply greater stress.

According to a method of the present invention, the shallow trench isolation is allowed by etch-filling to be deep and wide in the channel width direction and shallow and narrow in the channel length direction, and stress is applied to NMOS and PMOS simultaneously to increase the carrier is mobility of the channel region, thereby improving the overall driving capability of the device.

Although the present invention is described with reference to one or more exemplary embodiments, those skilled in the art know that a variety of suitable changes and equivalents can be made to the method of forming a device structure without departing from the scope of the present invention. Furthermore, from the teachings disclosed, many amendments suitable for specific situations or materials can be made without departing from the scope of the invention. Accordingly, the object of the present invention is not limited to particular embodiments used for achieving the best modes to carry out the present invention, while the device structure and its manufacturing method disclosed will include all embodiments that fall within the scope of the invention.

I/We claim:

1. A method for manufacturing a shallow trench isolation, comprising:
forming a hard mask layer on the substrate;
phottoetching/etching the hard mask layer and the substrate to form a plurality of first trenches along a first direction and a plurality of second trenches along a second direction perpendicular to the first direction, wherein to volume of the second trench is greater than that of the first trench;
depositing an insulating material in the first and second trenches; and
planarizing the insulating material and the hard mask layer until the substrate is exposed so as to form the shallow trench isolation.

2. The method for manufacturing the shallow trench isolation according to claim 1, wherein the hard mask layer comprises at least one material selected from a group consisting of silicon oxide, silicon nitride, and silicon oxynitride.

3. The method for manufacturing the shallow trench isolation according to claim 1, wherein the step for forming the plurality of first trenches and the plurality of second trenches further comprises:
phottoetching/etching the hard mask layer to form a hard mask pattern along the first direction until the substrate is exposed;
etching the substrate to form the first trenches;
phottoetching/etching the hard mask layer to form a hard mask pattern along the second direction until the substrate is exposed; and
etching the substrate to form the second trenches.

4. The method for manufacturing the shallow trench isolation according to claim 1, wherein the step for forming the plurality of first trenches and the plurality of second trenches further comprises:
phottoetching/etching the hard mask layer to form a hard mask pattern along the second direction until the substrate is exposed;
etching the substrate to form the second trenches;
phottoetching/etching the hard mask layer to form a hard mask pattern along the first direction until the substrate is exposed; and
etching the substrate to form first trenches.

5. The method for manufacturing the shallow trench isolation according to claim 1, wherein the step for forming the plurality of first trenches and the plurality of second trenches further comprises:
phottoetching/etching the hard mask layer to form a grid-like hard mask pattern having a plurality of openings along the first direction and the second direction; and
etching the substrate to forming the first trenches and the second trenches at the same time.

6. The method for manufacturing the shallow trench isolation according to claim 1, wherein the second trenches are wider than the first trenches.

7. The method for manufacturing the shallow trench isolation according to claim 1, wherein the second trenches are deeper than the first trenches.

8. The method for manufacturing the shallow trench isolation according to claim 1, wherein the insulating material comprises silicon oxide, silicon nitride, silicon oxynitride, Bi_{0.95}La_{0.05}NiO₃, BiNiO₃, or ZrW₂O₈.

9. The method for manufacturing the shallow trench isolation according to claim 1, wherein the shallow trench isolation applies tensile stress to the substrate.

10. The method for manufacturing the shallow trench isolation according to claim 1, wherein the first direction is a width direction of the device channel region, and the second direction is the length direction of the device channel region.

11. A semiconductor device, comprising:
a substrate; and
a shallow trench isolation formed of an insulating material in the substrate,
wherein a volume of the shallow trench isolation in the second direction is greater than a volume of the shallow trench isolation in the first direction.
